(19) United States
(12) Patent Application Publication
(10) Pub. No.: US 2014/0230889 A1
(43) Pub. Date: Aug. 21, 2014

(54) SOLAR CELL, METHOD FOR MANUFACTURING THE SAME AND SOLAR CELL MODULE

(71) Applicant: MOTECH INDUSTRIES, INC., New Taipei City (TW)

(72) Inventor: Hung-Chih CHANG, TAINAN CITY (TW)

(73) Assignee: MOTECH INDUSTRIES, INC., New Taipei City (TW)

(21) Appl. No.: 13/846,786

(22) Filed: Mar. 18, 2013

(30) Foreign Application Priority Data
Feb. 21, 2013 (TW) 102106019

(51) Int. Cl. H01L 31/0216

(52) U.S. Cl. CPC H01L 31/02167
USPC 136/256; 438/98

(57) ABSTRACT

A solar cell, a method for manufacturing the same and a solar cell module are described. The solar cell includes a substrate of a second conductivity type, an emitter layer, a first oxide layer, an auxiliary passivation layer, a back surface field layer, a second oxide layer, a first electrode and a second electrode. The substrate includes a first surface and a second surface opposite each other. The emitter layer, the first oxide layer and the auxiliary passivation layer are sequentially disposed on the first surface. Materials of the auxiliary passivation layer and the first oxide layer are different. The back surface field layer and the second oxide layer are sequentially disposed on the second surface. The first electrode is disposed above the first surface and contacts with the emitter layer. The second electrode is disposed above the second surface and contacts with the back surface field layer.

### RELATED APPLICATIONS

This application claims priority to Taiwan Application Serial Number 102106019, filed Feb. 21, 2013, which is herein incorporated by reference.

### FIELD OF THE INVENTION

The present invention relates to a photoelectric conversion device, and more particularly to a solar cell.

### BACKGROUND OF THE INVENTION

Types of substrates used in current solar cells include a P type and an N type. The efficiency of the solar cell constructed on the N-type substrate is much better than that constructed on the P-type substrate, so that a current tendency towards using the N-type substrate to manufacture the solar cell.

The solar cell using the N-type substrate usually uses a P-type conductive layer composed of a boron-doped layer as an emitter. A passivating method of an emitter surface of the solar cell is usually performed by forming a thermal oxide layer on the emitter surface as a passivation layer. However, the thermal oxide layer is not a good passivation layer for the boron emitter, so that the photoelectric conversion efficiency of the solar cell is poor. Accordingly, there is a need for a passivation technique, which can enhance the photoelectric conversion efficiency of the solar cell.

### SUMMARY OF THE INVENTION

Therefore, one aspect of the present invention is to provide a solar cell, a method for manufacturing the same and a solar cell module, in which an emitter layer of a first conductivity type on a substrate of a second conductivity is set with a passivation structure composed of an oxide layer and a passivation auxiliary layer stacked in sequence. The passivation structure has a superior passivation effect, so that the short circuit current (Jsc) and the open circuit voltage (Voc) of the solar cell are effectively increased, thereby enhancing photoelectric conversion efficiency of the solar cell.

Another aspect of the present invention is to provide a solar cell, a method for manufacturing the same and a solar cell module, in which a passivating method is used by firstly thrilling an oxide layer on an emitter layer of a first conductivity type on a substrate of a second conductivity type, and then forming an auxiliary passivation layer, so that the passivation structure has superior thermal stability, thereby increasing the process yield and reliability of the solar cell.

According to the aforementioned objectives, the present invention provides a solar cell. The solar cell includes a substrate of a second conductivity type, an emitter layer of a first conductivity type, a first oxide layer, an auxiliary passivation layer, a back surface field layer of the second conductivity type, a second oxide layer, a first electrode and a second electrode. The substrate includes a first surface and a second surface opposite to the first surface. The emitter layer is disposed in the substrate under the first surface. The first oxide layer is disposed on the emitter layer. The auxiliary passivation layer is disposed on the first oxide layer, in which materials of the auxiliary passivation layer and the first oxide layer are different from each other. The back surface field layer is disposed in the substrate under the second surface. The second oxide layer is disposed on the back surface field layer. The first electrode is disposed above the first surface and penetrates through the auxiliary passivation layer and the first oxide layer to contact with the emitter layer. The second electrode is disposed above the second surface and penetrates through the second oxide layer to contact with the back surface field layer.

According to a preferred embodiment of the present invention, the material of the auxiliary passivation layer is selected from the group consisting of aluminum oxide and a plurality of doped materials of the first conductivity type.

According to another preferred embodiment of the present invention, a material of the first oxide layer or/and the second oxide layer is selected from the group consisting of silicon oxide, titanium oxide, boron oxide and zinc oxide.

According to still another preferred embodiment of the present invention, the solar cell further includes a first dielectric layer disposed on the auxiliary passivation layer, in which the materials of the first dielectric layer and the auxiliary passivation layer are different from each other.

According, to further another preferred embodiment of the present invention, the material of the first dielectric layer includes silicon nitride,

According to yet another preferred embodiment of the present invention, the solar cell further includes a second dielectric layer disposed on the second oxide layer, in which materials of the second dielectric layer and the second oxide layer are different from each other in one example, the material of the second dielectric layer includes silicon nitride.

According to still further another preferred embodiment of the present invention, materials of the first electrode and the second electrode include silver and aluminum, in which a ratio of the aluminum is from 8% to 10%, the substrate is an N-type substrate, and the emitter layer is a boron emitter.

According to still further another preferred embodiment of the present invention, the solar cell is of a double-sided type, a light-receiving area of the first surface is larger than an area that the first electrode orthogonally projecting on the first surface, and a light-receiving area of the second surface is larger than an area that the second electrode orthogonally projecting on the second surface.

According to still further another preferred embodiment of the present invention, the doped materials of the first conductivity type are selected from the group consisting of boron doped amorphous silicon (a-Si:B) and boron doped amorphous silicon carbide (a-SiC:B).

According to the aforementioned objectives, the present invention further provides a solar cell module. The solar cell module includes an upper plate, a lower plate, a solar cell as described in the aforementioned description and at least one encapsulating material layer. The solar cell is disposed between the upper plate and the lower plate. The at least one encapsulating material layer is disposed between the upper plate and the lower plate to integrate the solar cell with the upper plate and the lower plate.

According to the aforementioned objectives, the present invention further provides a method for manufacturing a solar cell, which includes the following steps. A substrate of a second conductivity type is provided, in which the substrate includes a first surface and a second surface opposite to the first surface. An emitter layer of a first conductivity type is formed in the substrate under the first surface. A blocking layer is formed on the first surface to cover the emitter layer. A back surface field layer of the second conductivity type is formed in the substrate under the second surface. The blocking layer is removed. A first oxide layer and a second oxide layer are formed on the emitter layer and the back surface field layer respectively. An auxiliary passivation layer is formed on the first oxide layer, in which materials of the auxiliary passivation layer and the first oxide layer are different from each other. A first electrode is formed above the first surface and penetrates through the auxiliary passivation layer and the first oxide layer to contact with the emitter layer. A second electrode is formed above the second surface and penetrates through the second oxide layer to contact with the back surface field layer.

According to a preferred embodiment of the present invention, the material of the auxiliary passivation layer is selected from the group consisting of aluminum oxide and a plurality of doped materials of the first conductivity type.

According to another preferred embodiment of the present invention, a material of the first oxide layer or/and the second oxide layer is selected from the group consisting of silicon oxide, titanium oxide, boron oxide and zinc oxide.

According to still another preferred embodiment of the present invention, after the step of forming the auxiliary passivation layer, the method for manufacturing a solar cell further includes forming a first dielectric layer on the auxiliary passivation layer, in which the materials of the first dielectric layer and the auxiliary passivation layer are different from each other.

According to yet another preferred embodiment of the present invention, after the step of forming the second oxide layer, the method for manufacturing a solar cell further includes forming a second dielectric layer on the second oxide layer, in which materials of the second dielectric layer and the second oxide layer are different from each other. In one example, the material of the second dielectric layer includes silicon nitride.

According to still further another preferred embodiment of the present invention, materials of the first electrode and the second electrode include silver and aluminum, in which a ratio of the aluminum is from 8% to 10%, the substrate is an N-type substrate, and the emitter layer is a boron emitter.

According to still further another preferred embodiment of the present invention, the solar cell is of a double-sided type, a light-receiving area of the first surface is larger than an area that the first electrode orthogonally projecting on the first surface, and a light-receiving area of the second surface is larger than an area that the second electrode orthogonally projecting on the second surface.

According to still further another preferred embodiment of the present invention, the doped materials of the first conductivity type are selected from the group consisting of boron doped amorphous silicon (a-Si:B) and boron doped amorphous silicon carbide (a-SiC:B).

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1 illustrates a cross-sectional view of a solar cell module in accordance with an embodiment of the present invention;

FIG. 2 illustrates a cross-sectional view of a solar cell in accordance with an embodiment of the present invention; and

FIG. 3 through FIG. 6 are schematic diagrams showing a process for manufacturing a solar cell in accordance with an embodiment of the present invention.

### DETAILED DESCRIPTION OF THE PREFERRED EMBODIMENT

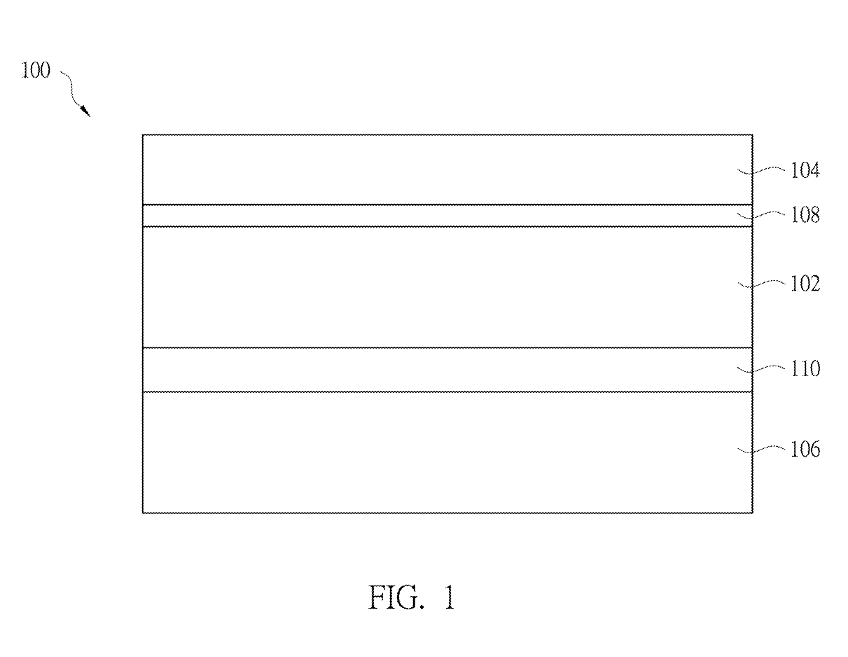

FIG. 1 illustrates a cross-sectional view of a solar cell module in accordance with an embodiment of the present invention. In the present embodiment, a solar cell module 100 mainly includes an upper plate 104, a lower plate 106, a solar cell 102, and one or more encapsulating material layer, such as encapsulating material layers 108 and 110.

As shown in FIG. 1, in the solar cell module 100, the solar cell 102 is disposed above the lower plate 106 and under the upper plate 104. Therefore, the upper plate 104 is disposed above the lower plate 106, and the solar cell 102 is disposed between the lower plate 106 and the upper plate 104. In addition, the two encapsulating material layers 108 and 110 are respectively disposed between the upper plate 104 and the solar cell 102 and between the lower plate 106 and the solar cell 102. With a high-temperature pressing procedure, the solar cell 102 can be integrated with the lower plate 106 and the upper plate 104 when the encapsulating material layers 108 and 110 melt.

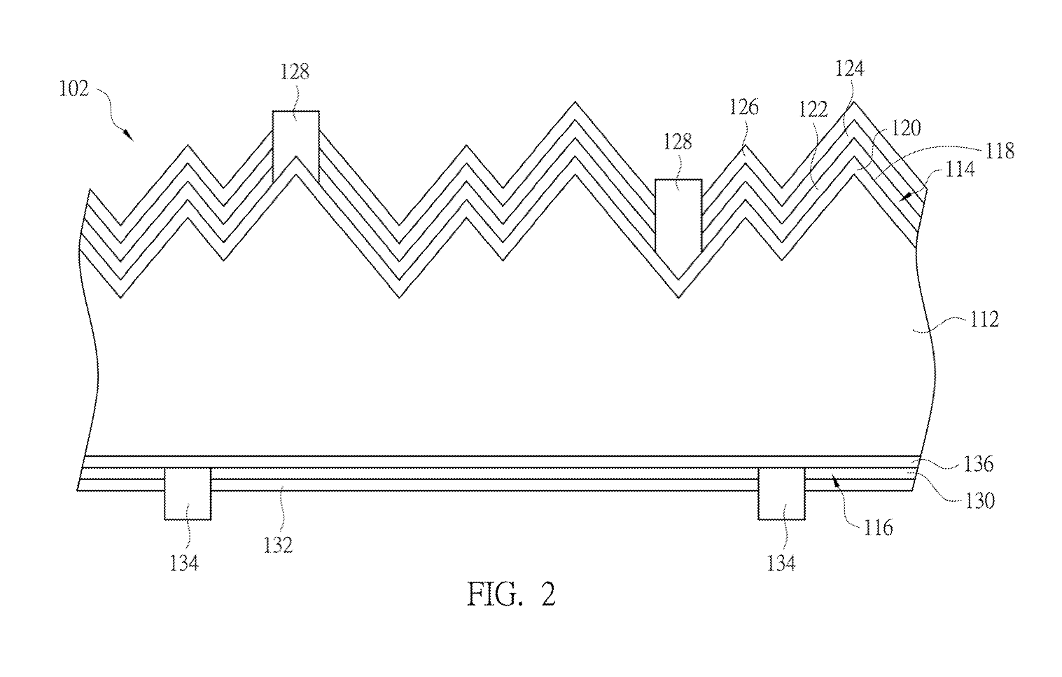

FIG. 2 illustrates a cross-sectional view of a solar cell in accordance with an embodiment of the present invention. In the present embodiment, the solar cell 102 may be a double-sided solar cell, so that both sides of the solar cell 102 can receive incident light. In one exemplary embodiment, the solar cell 102 mainly includes a substrate 112 of a second conductivity type, an emitter layer 120 of a first conductivity type, a first oxide layer 122, an auxiliary passivation layer 124, a back surface field layer 136 of the second conductivity type, a second oxide layer 130, a first electrode 128 and a second electrode 134. One of the first conductivity type and the second conductivity type may be a P type, and the other one may be an N type. In one preferred embodiment, the first conductivity type is a P type, and the second conductivity type is an N type.

The substrate 112 includes a first surface 114 and a second surface 116. The first surface 114 and the second surface 116 are on two opposite sides of the substrate 112. A material of the substrate 112 may be a semiconductor material, such as silicon. In one exemplary embodiment, the first surface 114 of the substrate 112 may be roughed to have rough structures 118, so as to increase an absorption rate of the solar cell 102 for incident light. In another exemplary embodiment, each of the first surface 114 and the second surface 116 of the substrate 112 may be roughed to have rough structures.

The emitter layer 120 may be disposed on the first surface 114 of the substrate 112. When the conductivity type of the substrate 112 is N, the emitter layer 120 may be a P-type doped layer, such as a boron-doped layer, formed on the first surface 114. In practice, the boron-doped layer is within the substrate 112 under the first surface 114 and adjacent to the first surface 114. The first oxide layer 122 may be disposed on the first surface 114 and contact with the emitter layer 120. In some exemplary embodiments, materials of the first oxide layer 122 may be selected from the group consisting of silicon nitride, titanium oxide, boron oxide and zinc oxide. In one example, a thickness of the first oxide layer 122 may be from 1 nm to 50 nm, for example. In one preferred embodiment, the thickness of the first oxide layer 122 may be from 2 nm to 10 nm.

In one exemplary example, when the material of the substrate 112 is silicon, the emitter layer 120 is a boron oxide (SiBₓ) doped layer, and the material of the first oxide layer 122 is zinc oxide, for example, the boron dopants in the boron oxide doped layer may diffuse into the first oxide layer 122 and may cause a substitution reaction in the first oxide layer 122 after a subsequent annealing process. The reaction may be simply expressed as: SiBₓ+ZnO→SiO₂:B+Zn. Therefore, after the annealing process, the first oxide layer 122 may be a combination of silicon dioxide doped with boron and metal elements. However, in one preferred embodiment, the material of the first oxide layer 122 may be silicon dioxide without metal elements.

The auxiliary passivation layer 124 is disposed on the first oxide layer 122. A material of the auxiliary passivation layer 124 is different from the material of the first oxide layer 122. In one exemplary embodiment, the material of the auxiliary passivation layer 124 may be selected from the group consisting of aluminum oxide and a plurality of doped materials of the first conductivity type. The doped materials of the first conductivity type may be a-Si:B or a-SiC:B, for example. In one example, a thickness of the auxiliary passivation layer 124 may be from 1 nm to 30 nm, for example. In one preferred embodiment, the thickness of the auxiliary passivation layer 124 may be from 1 nm to 10 nm.

In the present embodiment, the passivation structure of the solar cell 102 may be composed of the first oxide layer 122 and the auxiliary passivation layer 124. In addition to the first oxide layer 122 for providing the passivation effect, the auxiliary passivation layer 124 can enhance the passivation effect more effectively. Such a passivation structure has a superior passivation effect, so that the short circuit current and the open circuit voltage of the solar cell 102 can be effectively increased, thereby enhancing photoelectric conversion efficiency of the solar cell 102.

The back surface field layer 136 may be disposed on the second surface 116 of the substrate 112. In practice, the back surface field layer 136 is disposed within the substrate 112 under the second surface 116 and adjacent to the second surface 116. When the conductivity type of the substrate 112 is N, the back surface field layer 136 may be an N-type doped layer, such as a phosphorous-doped layer, formed on the second surface 116. The second oxide layer 130 may be disposed on the second surface 116 and contact with the back surface field layer 136. In some exemplary embodiments, materials of the second oxide layer 130 may be selected from the group consisting of silicon nitride, titanium oxide, boron oxide and zinc oxide.

The first electrode 128 is disposed above the first surface 114 of the substrate 112. In addition, the first electrode 128 penetrates through the auxiliary passivation layer 124 and the first oxide layer 122 in sequence to contact with the emitter layer 120 on the first surface 114, so as to form electrical connection. A material of the first electrode 128 may include silver and aluminum. When the material of the first electrode 128 includes silver and aluminum, a ratio of the aluminum is from 8% to 10%, in another exemplary embodiment, such as shown in FIG. 2, the solar cell 102 may optionally include a first dielectric layer 126. The first dielectric layer 126 may be disposed on the auxiliary passivation layer 124. A material of the first dielectric layer 126 is different from the material of the auxiliary passivation layer 124. The material of the first dielectric layer 126 may include silicon nitride, for example. The first dielectric layer 126 may be used as an antireflective layer of the first surface 114 of the solar cell 102 to increase a light absorption rate of the solar cell 102.

The second electrode 134 is disposed above the second surface 116 of the substrate 112. In addition, the second electrode 134 penetrates through the second oxide layer 130 to contact with the back surface field, layer 136 on the second surface 116, so as to form electrical connection. A material of the second electrode 134 may include silver and aluminum. In another exemplary embodiment, such as shown in FIG. 2, the solar cell 102 may optionally include a second dielectric layer 132. The second dielectric layer 132 may be disposed on the second oxide layer 130. A material of the second dielectric layer 132 is different from the material of the second oxide layer 130. The material of the second dielectric layer 132 may include silicon nitride, for example. The second dielectric layer 132 may be used as an antireflective layer of the second surface 116 of the solar cell 102 to increase a light absorption rate of the solar cell 102. In practice, when the second dielectric layer 132 is composed of silicon nitride, the silicon nitride may further passivate the back surface field layer 136 on the second surface 116 through the second oxide layer 130 (such as a silicon dioxide layer) to enhance the electrical effect of the cell.

In the present embodiment, the solar cell 102 is of a double-sided type. Therefore, a light-receiving area of the first surface 114, which excepts the region covered by the first electrode 128, is obviously larger than an area that the first electrode 128 orthogonally projecting on the first surface 114. Furthermore, a light-receiving area of the second surface 116, which excepts the region covered by the second electrode 134, is obviously larger than an area that the second electrode 134 orthogonally projecting on the second surface 116. That is, the first electrode 128 or the second electrode 134 does not completely cover the first surface 114 or the second surface 116.

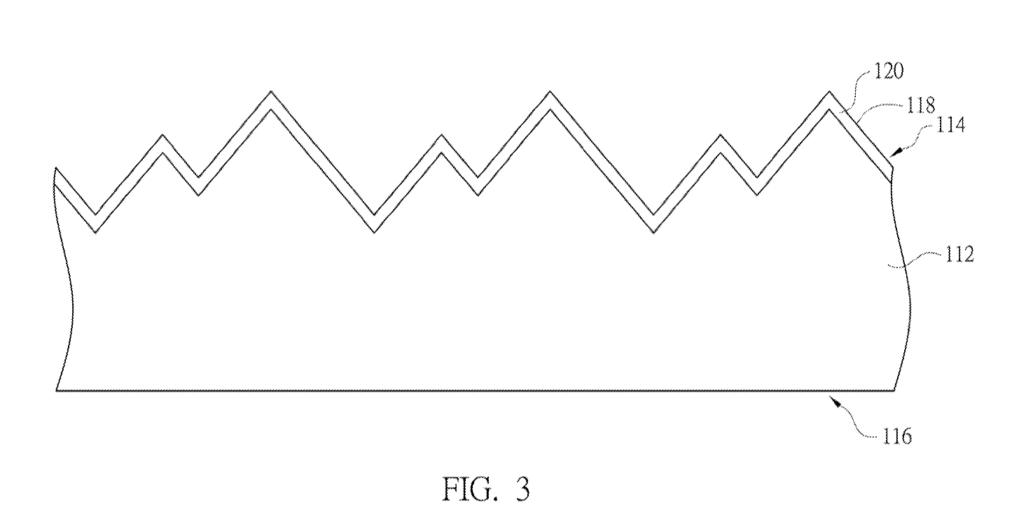

FIG. 3 through FIG. 6 are schematic diagrams showing a process for manufacturing a solar cell in accordance with an embodiment of the present invention. In the present embodiment, when the solar cell 102 shown in FIG. 2 is manufactured, the substrate 112 of the second conductivity type may be firstly provided. Then, in one exemplary embodiment, the first surface 114 of the substrate 112 of the second conductivity type may be roughed to form a plurality of rough structures 118 on the first surface 114 of the substrate 112. In another exemplary embodiment, the second surface 116 of the substrate 112 may be also roughed. In still another exemplary embodiment, the solar cell 102 is of a double-sided type, so that the first surface 114 and the second surface 116 of the substrate 112 may be roughed simultaneously.

Next, referring to FIG. 3, a doping process may be performed on the first surface 114 of the substrate 112 to form the emitter layer 120 of the first conductivity type on the first surface 114. The emitter layer 120 extends to cover the entire first surface 114. After forming the emitter layer 120, a doped portion formed under the second surface 116 of the substrate 112 during the doping process may be removed by an etching method according to the process requirement.

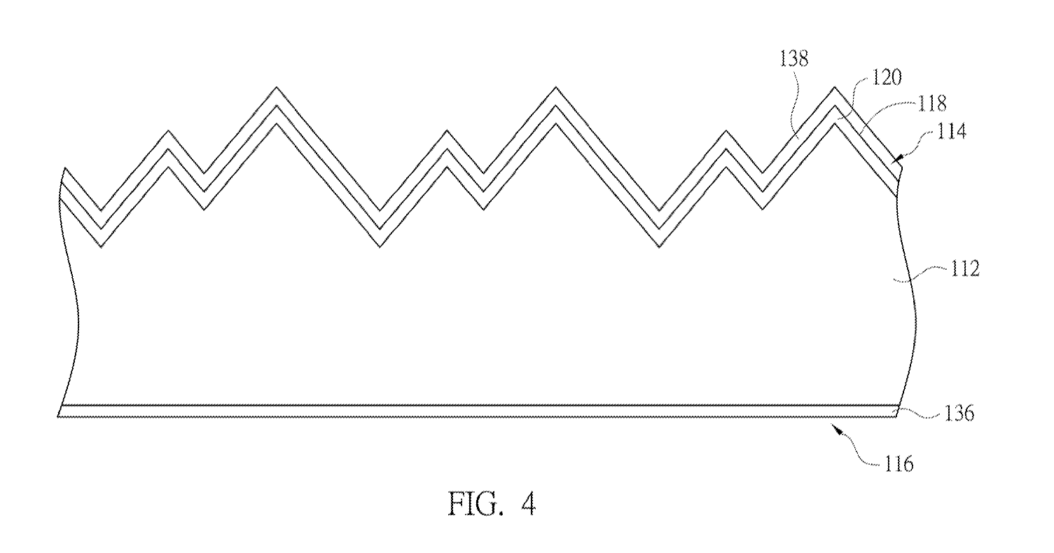

Then, referring to FIG. 4, a blocking layer 138 may be firstly formed to cover the emitter layer 120 by coating or depositing. A material of the blocking layer 138 may be photoresist, for example. Next, a doping process may be performed on the second surface 116 of the substrate 112 to form the back surface field layer 136 on the second surface 116. In one exemplary embodiment, the second surface 116 may be doped by using POCl₃, for example. The back surface field layer 136 extends to cover the entire second surface 116. When the second surface 116 is doped, it can prevent the second conductivity type dopants from entering the emitter layer 120 above the first surface 114 with the shield of the blocking layer 138.

Next, the blocking layer 138 is removed to expose the emitter layer 120. In one exemplary embodiment, when the doping process of the second surface 116 is performed by using POCl₃, a surface of the formed back surface field layer 136 may include phosphosilicate glass (PSG) formed thereon. Therefore, when the blocking layer 138 is removed, the phosphosilicate glass on the surface of the back surface field layer 136 may be simultaneously removed. In another exemplary embodiment, in order to prevent the first conductivity type dopants or the second conductivity type dopants from entering side surfaces of the substrate 112 to form electrical connection between the emitter layer 120 and the back surface field layer 136 while forming the emitter layer 120 and/or the back surface field layer 136, unnecessary doped regions in the substrate 112 are removed by, for example, an etching method to insulate the emitter layer 120 and the back surface field layer 136 while removing the blocking layer 138.

Then, the first oxide layer 122 and the second oxide layer 130 may be respectively formed on the emitter layer 120 and the back surface field layer 136 by, for example, a thermal oxidation method or a deposition method. In one exemplary embodiment, when the thermal oxidation method is used, the first oxide layer 122 and the second oxide layer 130 may be respectively and simultaneously formed on the emitter layer 120 and the back surface field layer 136. In the exemplary embodiment, the materials of the first oxide layer 122 and the second oxide layer 130 may be silicon oxide and boron oxide, for example. In another exemplary embodiment, the first oxide layer 122 and the second oxide layer 130 may be respectively but not simultaneously formed on the emitter layer 120 and the back surface field layer 136 by the deposition method. In the exemplary embodiment, the materials of the first oxide layer 122 and the second oxide layer 130 may be titanic oxide and zinc oxide, for example.

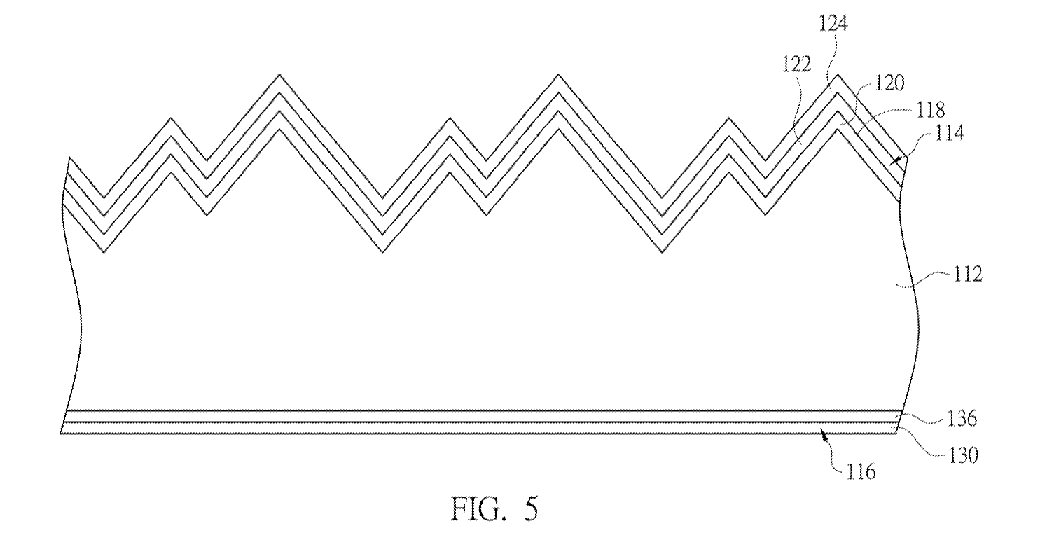

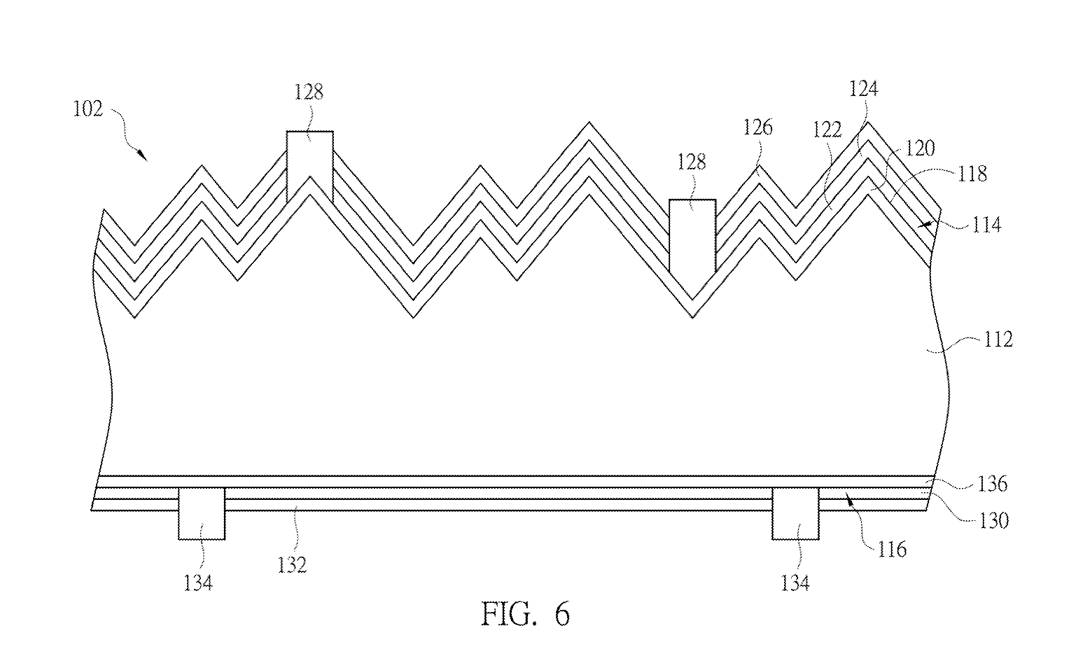

Next, in one exemplary embodiment, such as shown in FIG. 5, the auxiliary passivation layer 124 may be formed on the first oxide layer 122 by, for example, a deposition method. The auxiliary passivation layer 124 and the first oxide layer 122 collectively constitute the passivation structure on the first surface 114 of the substrate 112. Subsequently, such as shown in FIG. 6, the first dielectric layer 126 may be optionally formed on the auxiliary passivation layer 124 by, for example, a deposition method. As the aforementioned description, the first dielectric layer 126 may be used as an antireflective layer of the first surface 114 of the substrate 112.

In another exemplary embodiment, such as shown in FIG. 6, before the auxiliary passivation layer 124 is formed and after the second oxide layer 130 is formed, the second dielectric layer 132 may be optionally formed on the second oxide layer 130 by, for example, a deposition method. As the aforementioned description, the second dielectric layer 132 may be used as an antireflective layer of the second surface 116 of the substrate 112. In practice, when the second dielectric layer 132 is composed silicon nitride, the silicon nitride may further passivate the back surface field layer 136 on the second surface 116 through the second oxide layer 130 (such as a silicon dioxide layer) to enhance the electrical effect of the cell.

Subsequently, referring to FIG. 6 again, metal paste is printed on a region of the first surface 114, which the first electrode 128 is designed to be disposed on, and a region of the second surface 116, which the second electrode 134 is designed to be disposed on, by a screen printing method. Then, the metal paste respectively penetrates the first dielectric layer 126, the auxiliary passivation layer 124 and the first oxide layer 122 to contact with the emitter layer 120, and penetrates the second dielectric layer 132 and the second oxide layer 130 to contact with the back surface field layer 136 through a firing process with temperature of 800° C., to 900° C., so as to form the first electrode 128 on the first surface 114 and the second electrode 134 on the second surface 116 to finish the manufacture of the solar cell 102.

According to the aforementioned embodiments of the present invention, one advantage of the present invention is that a passivation structure composed of an oxide layer and a passivation auxiliary layer stacked in sequence is disposed on an emitter layer of a first conductivity type (i.e. a P-type boron doped emitter layer) on a substrate of a second conductivity, and the passivation structure has a superior passivation effect, so that the short circuit current and the open circuit voltage of the solar cell are effectively increased, thereby enhancing photoelectric conversion efficiency of the solar cell.

According to the aforementioned embodiments of the present invention, another advantage of the present invention is that a passivating method is used by firstly forming an oxide layer on an emitter layer of a first conductivity type (i.e. a P-type boron doped emitter layer) on a substrate of a second conductivity type, and then forming an auxiliary passivation layer, so that the passivation structure has superior thermal stability, thereby increasing the process yield and reliability of the solar cell.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A solar cell including:
a substrate of a second conductivity type including a first surface and a second surface opposite to said first surface;
an emitter layer of a first conductivity type disposed in said substrate under said first surface;
a first oxide layer disposed on said emitter layer;
an auxiliary passivation layer disposed on said first oxide layer, wherein materials of said auxiliary passivation layer and said first oxide layer are different from each other;
a back surface field layer of said second conductivity type disposed in said substrate under said second surface;
a second oxide layer disposed on said back surface field layer;
a first electrode disposed above said first surface and penetrating through said auxiliary passivation layer and said first oxide layer to contact with said emitter layer; and
a second electrode disposed above said second surface and penetrating through said second oxide layer to contact with said back surface field layer.

2. The solar cell according to claim 1, wherein the material of said auxiliary passivation layer is selected from the group consisting of aluminum oxide and a plurality of doped materials of said first conductivity type.

3. The solar cell according to claim 2, wherein a material of said first oxide layer or/and said second oxide layer is selected from the group consisting of silicon oxide, titanium oxide, boron oxide and zinc oxide.

4. The solar cell according to claim 2, further including a first dielectric layer disposed on said auxiliary passivation layer, wherein the materials of said first dielectric layer and said auxiliary passivation layer are different from each other.

5. The solar cell according to claim 4, wherein the material of said first dielectric layer includes silicon nitride.

6. The solar cell according to claim 2, further including a second dielectric layer disposed on said second oxide layer, wherein materials of said second dielectric layer and said second oxide layer are different from each other.

7. The solar cell according to claim 6, wherein the material of said second dielectric layer includes silicon nitride.

8. The solar cell according to claim 2, wherein a material of said first electrode includes silver and aluminum, wherein a ratio of said aluminum is from 8% to 10%, said substrate is an N-type substrate, and said emitter layer is a boron emitter.

9. The solar cell according to claim 2, wherein said solar cell is of a double-sided type, a light-receiving area of said first surface is larger than an area that said first electrode orthogonally projecting on said first surface, and a light-receiving area of said second surface is larger than an area that said second electrode orthogonally projecting on said second surface.

10. The solar cell according to claim 2, wherein the doped materials of said first conductivity type are selected from the group consisting of boron doped amorphous silicon (a-Si:B) and boron doped amorphous silicon carbide (a-SiC:B).

11. A solar cell module, including:
an upper plate;
a lower plate;
a solar cell as claimed in claim 1 disposed between said upper plate and said lower plate; and
at least one encapsulating material layer disposed between said upper plate and said lower plate to integrate said solar cell with said upper plate and said lower plate.

12. A method for manufacturing a solar cell, including:
providing a substrate of a second conductivity type, wherein said substrate includes a first surface and a second surface opposite to said first surface;
forming an emitter layer of a first conductivity type in said substrate under said first surface;
forming a blocking layer on said first surface to cover said emitter layer;
forming a back surface field layer of said second conductivity type in said substrate under said second surface;
removing said blocking layer;
forming a first oxide layer and a second oxide layer respectively on said emitter layer and said back surface field layer;
forming an auxiliary passivation layer on said first oxide layer, wherein materials of said auxiliary passivation layer and said first oxide layer are different from each other;
forming a first electrode above said first surface and penetrating through said auxiliary passivation layer and said first oxide layer to contact with said emitter layer; and
forming a second electrode above said second surface and penetrating through said second oxide layer to contact with said back surface field layer.

13. The method for manufacturing a solar cell according to claim 12, wherein the material of said auxiliary passivation layer is selected from the group consisting of aluminum oxide and a plurality of doped materials of said first conductivity type.

14. The method for manufacturing a solar cell according to claim 13, wherein a material of said first oxide layer or/and said second oxide layer is selected from the group consisting of silicon oxide, titanium oxide, boron oxide and zinc oxide.

15. The method for manufacturing a solar cell according to claim 13, further including forming a first dielectric layer on said auxiliary passivation layer after the step of forming said auxiliary passivation layer, wherein the materials of said first dielectric layer and said auxiliary passivation layer are different from each other.

16. The method for manufacturing a solar cell according to claim 13, further including forming a second dielectric layer on said second oxide layer after the step of forming said second oxide layer, wherein materials of said second dielectric layer and said second oxide layer are different from each other.

17. The method for manufacturing a solar cell according to claim 16, wherein the material of said second dielectric layer includes silicon nitride.

18. The method for manufacturing a solar cell according to claim 13, wherein a material of said first electrode includes silver and aluminum, a ratio of said aluminum is from 8% to 10%, said substrate is an N-type substrate, and said emitter layer is a boron emitter.

19. The method for manufacturing a solar cell according to claim 13, wherein said solar cell is of a double-sided type, a light-receiving area of said first surface is larger than an area that said first electrode orthogonally projecting on said first surface, and a light-receiving area of said second surface is larger than an area that said second electrode orthogonally projecting on said second surface.

20. The method for manufacturing a solar cell according to claim 13, wherein the doped materials of said first conductivity type are selected from the group consisting of boron doped amorphous silicon (a-Si:B) and boron doped amorphous silicon carbide (a-SiC:B).
